(19) United States
(12) Patent Application Publication
(10) Pub. No.: US 2024/0128077 A1
(43) Pub. Date: Apr. 18, 2024

(54) SEMICONDUCTOR DEVICE AND A METHOD FOR FILM DEPOSITION

(71) Applicant: NANYA TECHNOLOGY CORPORATION, New Taipei City (TW)

(72) Inventor: JI-FENG LIU, NEW TAIPEI CITY (TW)

(21) Appl. No.: 17/966,110

(22) Filed: Oct. 14, 2022

(51) Int. Cl. H01L 21/02; H01L 23/31

(52) U.S. Cl. CPC H01L 21/02274; H01L 23/3171

(57) ABSTRACT

A semiconductor device and a method and tool for film deposition are provided. The method of film deposition includes holding a semiconductor device in a chamber by a holding component, wherein the chamber is defined by a showerhead and a pedestal, providing reacting gases by the showerhead from a bottom side of the chamber, and forming a first dielectric layer on a backside surface of the semiconductor device.

### TECHNICAL FIELD

The present disclosure relates to a semiconductor device and a method for film deposition.

### DISCUSSION OF THE BACKGROUND

During processing of semiconductor devices, warpage may occur due to mismatch of mechanical properties between layers. Such warpage can severely increase overlay errors in the semiconductor device.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a method of film deposition including providing a semiconductor device including an active surface and a backside surface opposite to the active surface, holding the backside surface of the semiconductor device by a holding component, and forming a dielectric layer on the backside surface of the semiconductor device.

Another aspect of the present disclosure provides a method of film deposition including holding a semiconductor device in a chamber by a holding component, wherein the chamber is defined by a showerhead and a pedestal, providing reacting gases by the showerhead from a bottom side of the chamber, and forming a first dielectric layer on a backside surface of the semiconductor device.

Another aspect of the present disclosure provides a semiconductor device including an active surface, a backside surface, and a dielectric layer. The active surface is opposite to the backside surface. The dielectric layer is disposed on a first portion of the backside surface. The active surface of the semiconductor device is free from passivation layer remnants.

Another aspect of the present disclosure provides a film deposition tool, including a pedestal, a showerhead, and a holding component. The showerhead is disposed under the pedestal. The holding component is disposed closer to the pedestal than the showerhead. The holding component has a holding surface facing the pedestal and configured to hold a backside surface of a semiconductor device.

In some embodiments, the backside surface of the semiconductor device has a first portion covered by the holding component, the holding component comprises a plurality of protruding portions in contact with the first portion of the backside surface of the semiconductor device, and the showerhead is configured to provide reacting gases and the pedestal is configured to provide neutral gases

The method of film deposition of the present disclosure includes providing a semiconductor device including an active surface and a backside surface opposite to the active surface, holding the backside surface of the semiconductor device by a holding component, and forming a dielectric layer on the backside surface of the semiconductor device to form the semiconductor device. The method of the present disclosure enables direct formation of the dielectric layer on the backside surface of the semiconductor device in a single step to form the semiconductor device. The recited single step method reduces costs and improves throughput. Since the active surface of the semiconductor device is physically separated from any part of a tool implementing the inventive method, no passivation layer (or protective layer) need be deposited on the active surface of the semiconductor device. As such, the active surface of the semiconductor device remains free from passivation layer remnants or damage induced when removing the passivation layer. In the method of the present disclosure, the dielectric layer is directly formed on the backside surface of the semiconductor device in a single step without flipping or forming or removing passivation layer. The active surface of the semiconductor device is intact during formation of the dielectric layer on the backside surface thereof, preventing any of the passivation layer remaining and/or any damage or characteristics shift induced during the removal of the passivation layer. Furthermore, in the method of the present disclosure, the dielectric layer is directly formed on the backside surface of the semiconductor device in a single step without forming or removing any temporary layer (e.g., the passivation layer). Based on the values of bow of the semiconductor device before formation of the dielectric layer, the thickness or type of the dielectric layer may be determined to compensate for warpage of the semiconductor device to a significantly low extent, e.g., value of bows around +/−1 μm.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a schematic diagram of a film deposition tool in accordance with some embodiments of the present disclosure.

FIG. 2 is an underside view of a holding component and a semiconductor device in FIG. 1 in accordance with some embodiments of the present disclosure.

FIG. 3 is a schematic diagram of a film deposition tool in accordance with some embodiments of the present disclosure.

FIG. 4 is an underside view of a holding component and a dielectric layer in FIG. 3 in accordance with some embodiments of the present disclosure.

FIG. 5 is a schematic diagram of a semiconductor device in accordance with some embodiments of the present disclosure.

FIG. 6 is an underside view of the semiconductor device in FIG. in accordance with some embodiments of the present disclosure.

FIG. 7 is a flowchart of a method of film deposition, in accordance with some embodiments of the present disclosure.

FIG. 8 is a distribution of values of bow of a semiconductor device in accordance with some embodiments of the present disclosure.

FIG. 9 is a distribution of values of bow of a semiconductor device in accordance with some embodiments of the present disclosure.

FIG. 10 is a distribution of values of overlay of a semiconductor device in accordance with some embodiments of the present disclosure.

FIG. 11 is a flowchart of a method of film deposition, in accordance with some embodiments of the present disclosure.

FIG. 12 is a flowchart of a method of film deposition, in accordance with some embodiments of the present disclosure.

FIG. 13 is a flowchart of a method of film deposition, in accordance with some embodiments of the present disclosure.

FIG. 14 is a schematic diagram of a film deposition tool in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

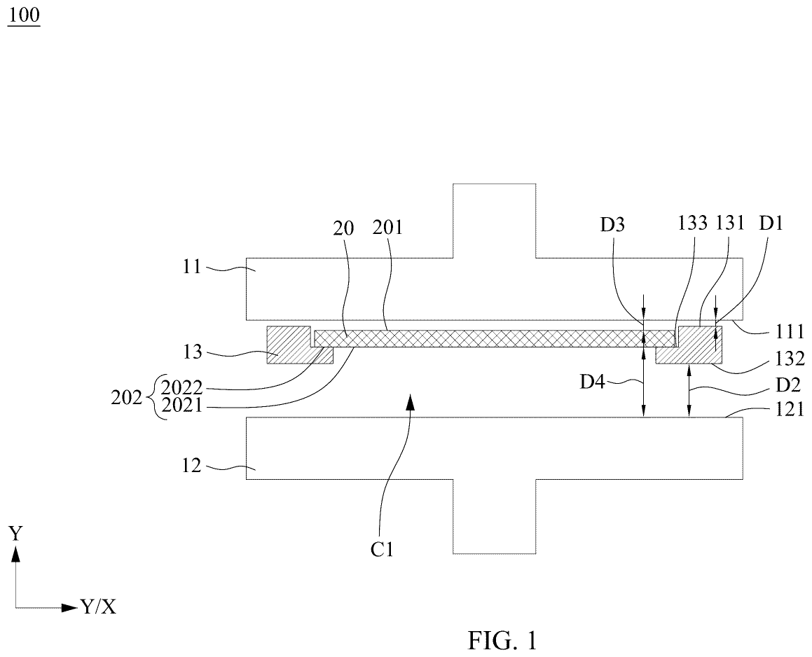

FIG. 1 is a schematic diagram of a tool 100 for film deposition in accordance with some embodiments of the present disclosure. The tool 100 includes a pedestal 11, showerhead 12, and a holding component 13. The pedestal 11 is arranged above the showerhead 12. The showerhead 12 is arranged below the showerhead 12. The pedestal 11 has a surface (or a bottom side surface) 111 facing the showerhead 12. The showerhead 12 has a surface (or a top surface) 121 facing the pedestal 11. The pedestal 11 and the showerhead 12 define a chamber C1. The chamber C1 has a top side, i.e., the surface 111 of the pedestal 11 and a bottom side, i.e., the surface 121 of the showerhead 12. The chamber C1 may be a vacuum chamber with pressures ranging from atmospheric pressure to below, for example, 10⁻⁸ Torr.

The holding component 13 is arranged between the pedestal 11 and the shower head 12. The holding component 13 has a surface 131 and a surface 132 opposite to the surface 131. The surface 131 of the holding component 13 faces the pedestal 11 (or the surface 111 of the pedestal 11). The surface 132 of the holding component 13 faces the showerhead 12 (or the surface 121 of the showerhead 12). The holding component 13 further has a holding surface 133 between the surface 131 and the surface 132 of the holding component 13. The holding surface 133 of the holding component 13 faces the pedestal 11. The holding surface 133 of the holding component 13 faces away from the showerhead 12. The holding component 13 is within the chamber C1. A first distance D1 between the surface 131 of the holding component 13 and the surface 111 of the pedestal 11 is less than a second distance D2 between the surface 132 of the holding component 13 and the surface 121 of the showerhead 12.

As shown in FIG. 1, the holding component 13 (or the holding surface 133) may be configured to hold or support a semiconductor device 20. The semiconductor device 20 may include, for example, but is not limited to, a substrate, a carrier, a wafer, a package, a semiconductor chip, or any device that includes semiconductor dies or chips. Furthermore, the tool 100 may include one or more ports (not shown) configured to load or unload the semiconductor device 20 and the holding component 13 may be actuated by a robot arm or other suitable actuating members (not shown) to receive the semiconductor device 20. The holding component 13 may be configured to move configured to move in at least one of directions x, y, or z (along the x-axis, y-axis, or z-axis).

As shown in FIG. 1, the semiconductor device 20 has an active surface 201 and a backside surface 202 opposite to the active surface 201. The active surface 201 of the semiconductor device 20 faces the pedestal 11. The backside surface 202 of the semiconductor device 20 faces the showerhead 12. A third distance D3 between the active surface 201 of the semiconductor device 20 and the surface 111 of the pedestal 11 is less than a fourth distance D4 between the backside surface 202 of the semiconductor device 20 and the surface 121 of the showerhead 12.

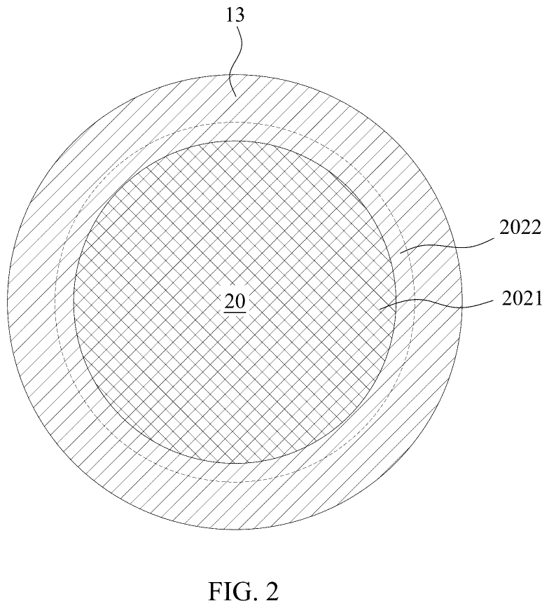

The backside surface 202 of the semiconductor device 20 includes a portion 2021 and a portion 2022. The portion 2021 may be a central portion of the backside surface 202 of the semiconductor device 20. The portion 2021 may be an edge portion of the backside surface 202 of the semiconductor device 20. FIG. 2 is an underside view of the holding component 13 and the semiconductor device 20 in FIG. 1 in accordance with some embodiments of the present disclosure. The portion 2021 is surrounded by the portion 2022. The portion 2021 is exposed by the holding component 13. The portion 2021 is not in contact with the holding component 13. The portion 2022 is covered by the holding component 13. In some embodiments, the portion 2022 is covered by the holding surface 133 of the component 13. The portion 2022 may be in contact with the holding surface 133 of the component 13. The holding component 13 may be annular in shape.

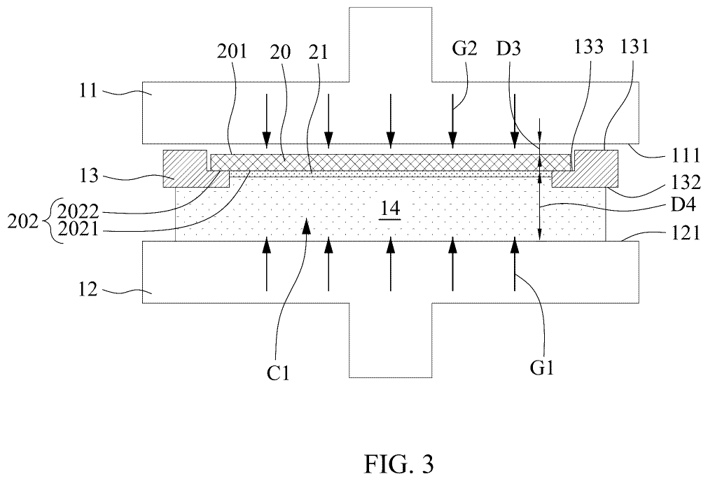

FIG. 3 is a schematic diagram of the tool 100 for film deposition in accordance with some embodiments of the present disclosure. In some embodiments, FIG. 3 illustrates the formation of a film on the backside surface 202 of the semiconductor device 20.

The showerhead 12 may be configured to provide reacting gases G1. The showerhead 12 may include a plurality of outlets to distribute the reacting gases G1 into the chamber C1. The reacting gases G1 may flow from a bottom side, i.e., the surface 121 of the showerhead 12 to the backside surface 202 of the semiconductor device 20.

The pedestal 11 may be configured to provide neutral gases G2. The pedestal 11 may include a plurality of outlets to distribute the neutral gases G2 into the chamber C1. The neutral gases G2 may flow from a top side, i.e., the surface 111 of the pedestal 11 to the active surface 201 of the semiconductor device 20. The neutral gases G2 may purge a plasma or reacting gas G1 from the active surface 201 of the semiconductor device 20. As such, no dielectric material is deposited on the active surface 201 of the semiconductor device 20.

In some embodiments, the pedestal 11 may include a plate electrode. The showerhead 12 may include a plate electrode. The plate electrode of the pedestal 11 and the plate electrode of the showerhead 12 may be electrically coupled to a radio frequency generator (not shown) for generating a plasma 14. The reacting gas G1 may interact with the plasma 14. In some embodiments, the energy of the plasma 14 is transferred into the reacting gas G1, transforming the reacting gas G1 into reactive radicals, ions and other highly excited species. The energetic species of the reacting gases G1 then flow over the backside surface 202 of the semiconductor device 20, where they are deposited as a dielectric material or a thin film. After the deposition of the dielectric material, a dielectric layer 21 is formed on the backside surface 202 of the semiconductor device 20. In the present disclosure, one example of the tool 100 for film deposition pertains to plasma enhanced chemical vapor reaction (PECVD). The dielectric layer 21 may include a thin film. This embodiment does not limit the scope of the claimed invention and is only for the purposes of explanation. Persons of ordinary skill in the art would understand that the dielectric layer 21 may be formed in a chemical vapor reaction (CVD) process or physical vapor reaction (PVD) process. The CVD process may include atmosphere pressure (AP) CVD, low pressure (LP) CVD, PECVD, or the like. The PVD process may include sputtering PVD, evaporative PVD, ion plating PVD, or the like.

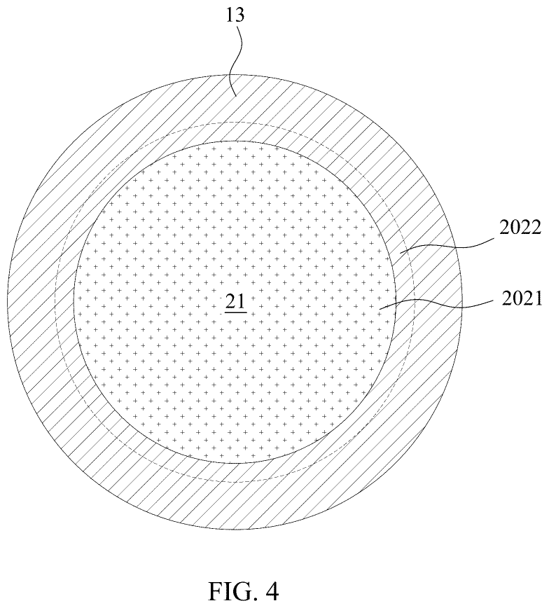

FIG. 4 is an underside view of the holding component 13 and the dielectric layer 21 in FIG. 3 in accordance with some embodiments of the present disclosure. As shown in FIG. 4, the dielectric layer 21 is formed on the portion 2021 of the backside surface 202 of the semiconductor device 20. Since the portion 2022 of the backside surface 202 of the semiconductor device 20 is covered by the holding component 13, no dielectric material or only a few dielectric material is deposited on the portion 2022 of the backside surface 202 of the semiconductor device 20. The dielectric layer 13 may partially cover the backside surface 202 of the semiconductor device 20.

The dielectric layer 13 may include silicon nitride, silicon oxide or the like. In alternative embodiments, by changing the precursors or the reacting gases, the tool 100 for film deposition may deposit metal materials on the backside surface 202 of the semiconductor device 20.

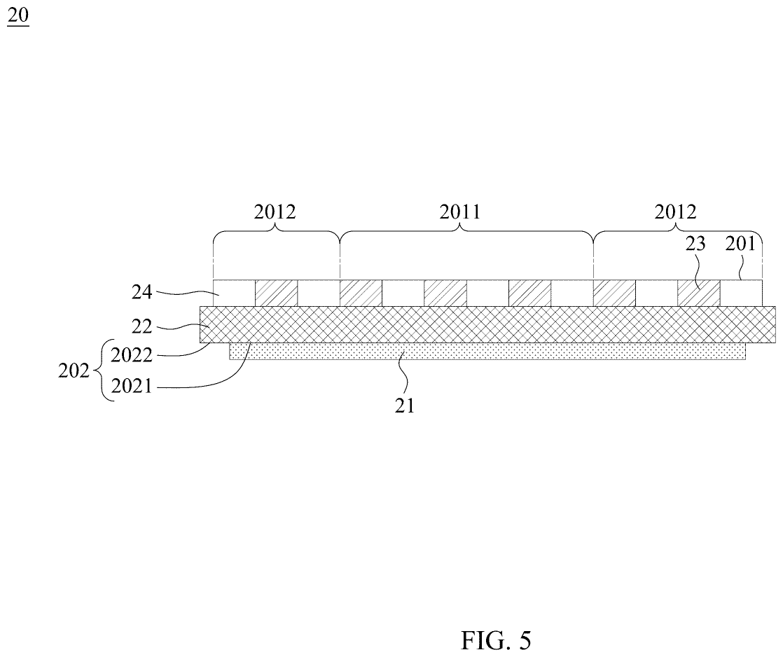

FIG. 5 is a schematic diagram of the semiconductor device 20 in accordance with some embodiments of the present disclosure. The semiconductor device 20 includes a substrate 22, the dielectric layer 21, a plurality of semiconductor dies 23, and a dielectric layer 24. The substrate 22 may include a doped semiconductor wafer.

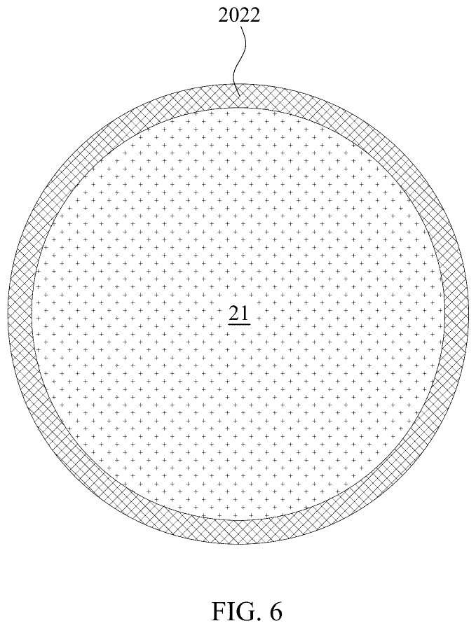

The dielectric layer 21 is disposed on the substrate 22. FIG. 6 is an underside view of the semiconductor device in FIG. 5 in accordance with some embodiments of the present disclosure. The portion 2022 of the backside surface 202 of the semiconductor device 20 is exposed by the dielectric layer 13. The portion 2022 of the backside surface 202 of the semiconductor device 20 may be annular in shape.

Referring again to FIG. 5, the plurality of semiconductor dies 23 are disposed adjacent to the active surface 201 of the semiconductor device 20, while no semiconductor dies 23 may be disposed adjacent to the backside surface 202 of the semiconductor device 20. The active surface 201 of the semiconductor device 20 may be free from passivation layer remnants. The active surface 201 of the semiconductor device 20 may have substantially flat topography. The active surface 201 of the semiconductor device 20 may include a portion (or a central portion) 2011 and a portion (or an edge portion) 2012 surrounds the portion 2011. The roughness of the central portion 2011 of the active surface 201 and the edge portion 2012 of the active surface 201 may be substantially the same.

The plurality of the semiconductor dies 23 are disposed on the substrate 20. The plurality of the semiconductor dies 23 may be surrounded by the dielectric layer 24. The dielectric layer 24 may include interlayer dielectrics (ILD). The semiconductor dies 23 may include an integrated circuit, a logic device, a processor, a controller (e.g. a memory controller), a microcontroller, a memory die, a high-speed input/output device or other electronic components. The semiconductor dies 23 may include a plurality of active components, such as transistors.

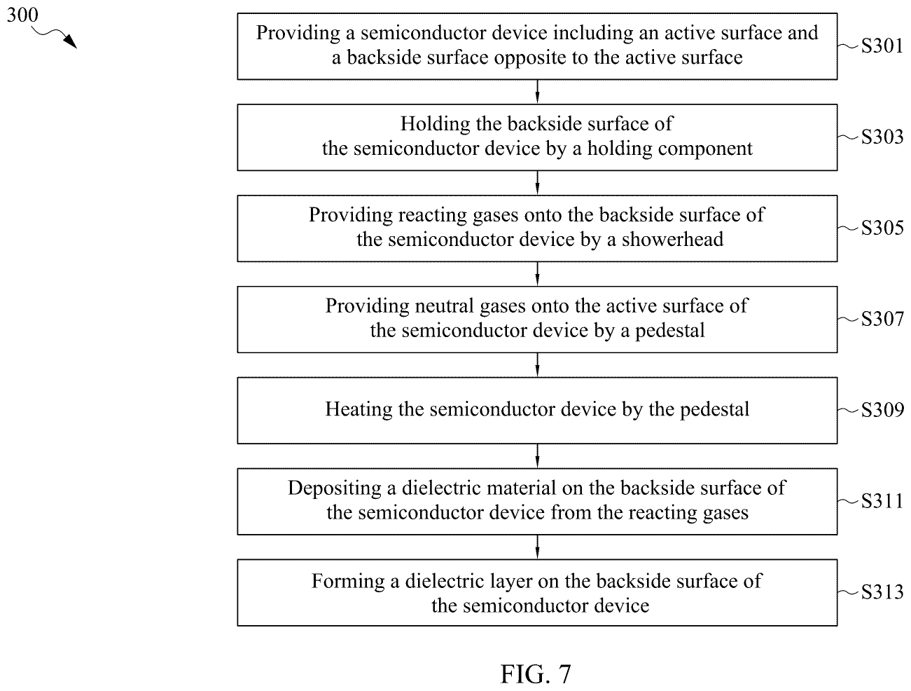

FIG. 7 is a flowchart of a method 300 of film deposition, in accordance with some embodiments of the present disclosure. The method 300 may be implemented by the tool 100 for film deposition.

The method 300 begins with operation S301 including providing a semiconductor device (e.g., the semiconductor device 20) including an active surface and a backside surface (e.g., active surface 201 and the backside surface 202 of the semiconductor device 20) opposite to the active surface. Prior to the operation S301, the method may further include loading the semiconductor device 20 via a port of the tool 100 for film deposition.

The method 300 continues with operation S303 including holding the backside surface of the semiconductor device by a holding component (e.g., the holding component 13 of the film deposition tool). Prior to the operation S303, the method 300 may further include actuating holding component 13 to receive the semiconductor device 20.

In some embodiments, holding the backside surface of the semiconductor device may further include holding the backside surface of the semiconductor device by a holding surface (e.g., the holding surface 133) of the holding component. The holding surface faces a pedestal (e.g., the pedestal 11 of the tool 100 for film deposition). In some embodiments, holding the backside surface of the semiconductor device may further locating the semiconductor device, such that the backside surface of the semiconductor device faces a showerhead (e.g., the showerhead 12 of the tool 100 for film deposition) and the active surface of the semiconductor device faces the pedestal. In some embodiments, holding the backside surface of the semiconductor device may further exposing a portion (e.g., the portion 2021 of the backside surface 202) of the backside surface by the holding component.

In some embodiments, holding the backside surface of the semiconductor device may further include locating the semiconductor device closer to the pedestal than the showerhead. A distance (e.g., the distance D3) between the active surface of the semiconductor device and the surface of the pedestal is less than a distance (e.g., the distance D4) between the backside surface of the semiconductor device and the surface of the showerhead.

The method 300 continues with operation S305 including providing reacting gases (e.g., the reacting gases G1) onto the backside surface of the semiconductor device by a showerhead (e.g., the showerhead 12 of the tool 100 for film deposition). The method 300 may further include distributing the reacting gases through a plurality of outlets of the showerhead.

The method 300 continues with operation S307 including providing neutral gases (e.g., the neutral gases G2) onto the active surface of the semiconductor device by a pedestal (e.g., the pedestal 11 of the tool 100 for film deposition). The method may further include distributing the neutral gases through a plurality of outlets of the pedestal. The method 300 may further include purging the reacting gases from the active surface of the semiconductor device by the neutral gases. As such, no dielectric material is deposited on the active surface of the semiconductor device.

The method 300 continues with operation S309 including heating of the semiconductor device by the pedestal. The temperature of the semiconductor device may be increased to reach a predetermined degree to facilitate the deposition of dielectric material. The temperature of semiconductor device may depend on the type of the dielectric material that is intended to deposit.

The method 300 continues with operation S311 including depositing a dielectric material on the backside surface of the semiconductor device from the reacting gases. In some embodiments, depositing the dielectric material may include pyrolytically decompositing the reacting gases on the substrate to provide a coating of a solid reaction product.

The method 300 continues with operation S313 including forming a dielectric layer (e.g., the dielectric layer 21) on the backside surface of the semiconductor device. In some embodiments, forming the dielectric layer may include forming the dielectric layer on an exposed portion of the backside surface of the semiconductor device. The dielectric layer may not be formed on a covered portion of the backside surface of the semiconductor device. Owing to the existence of the neutral gas over the active surface of the semiconductor device, the dielectric layer may not be formed on the active surface of the semiconductor device. After the step S313, the method may further include unloading the semiconductor device via a port of the film deposition tool.

The method 300 is merely an example, and is not intended to limit the present disclosure beyond what is explicitly recited in the claims. Additional operations can be provided before, during, or after each operation of the method 300, and some operations described can be replaced, eliminated, or reordered for additional embodiments of the method. In some embodiments, the method 300 can include further operations not depicted in FIG. 7. In some embodiments, the method 200 can include one or more operations depicted in FIG. 7.

The method 300 of the present disclosure enables direct formation of the dielectric layer on the backside surface of the semiconductor device in a single step to form the semiconductor device. The single step method reduces costs and improves the throughput of the manufacture of the semiconductor device. Since the active surface of the semiconductor device is physically separated from any parts of the film deposition tool, no passivation layer (or protective layer) need be deposited on the active surface of the semiconductor device. As such, the active surface of the semiconductor device may be free from any passivation layer remnants or any damage induced when removing the passivation layer.

In some comparative embodiments, multi-step processes are implemented for the purposed of forming a dielectric layer on a backside surface of a wafer to ease the warpage thereof. The multi-step processes may include at least forming a passivation layer on an active surface of the wafer, such that the active surface is protected by the passivation layer, flipping the wafer before loading into a tool for implementing the formation of the dielectric layer on the backside surface, holding the active surface of the wafer via the protective layer, depositing dielectric material on the backside surface of the wafer to form the dielectric layer, and removing the passivation layer by, for example, dry or wet etching or polishing. However, in some cases, the passivation layer may remain on the active surface if the time of etching or polishing for the removal of the passivation layer is insufficient. In some cases, it is possible to completely remove the passivation layer by means of over-etching or over-polishing. However, the active surface of the wafer, in which semiconductor dies are disposed, may be damaged, e.g., scratch, or the characteristics thereof may shift (e.g., critical dimension, profile, thickness, or topography). In the method 300 of the present disclosure, the dielectric layer is directly formed on the backside surface of the semiconductor device in a single step without flipping or forming or removing any temporary layer (e.g., passivation layer). The active surface of the semiconductor device is intact during the formation of the dielectric layer on the backside surface thereof, preventing any remains of the passivation layer and/or any damage or characteristics shift induced during the removal of the passivation layer. Thus, the active surface 201 of the semiconductor device 20 may have substantially flat topography and the roughness of the central portion 2011 of the active surface 201 and the edge portion 2012 of the active surface 201 may be substantially the same.

Furthermore, in the comparative embodiments, in order to ease the warpage of the wafer, a value of bow of the wafer may be measured in advance. It is expected that the value of bow of the wafer may be compensated or decreased after the dielectric layer is formed on the backside surface of the wafer. However, any formation or removal of a layer on the wafer may inevitably alter the value of bow of the wafer. In other words, when forming the passivation layer on the active surface of the wafer, forming the dielectric layer on the backside surface of the wafer, and removing the passivation layer, the value of bows of the wafer can experience an independent and distinct change, rendering the compensation of the warpage of the wafer unstable and hard to predict. Therefore, the value of bow of the wafer may not be effectively decreased. In the method 300 of the present disclosure, the dielectric layer is directly formed on the backside surface of the semiconductor device in a single step without forming or removing any temporary layer (e.g., passivation layer). Based on the values of bow of the semiconductor device before the formation of the dielectric layer, the thickness or type of the dielectric layer may be determined to compensate the warpage of the semiconductor device to a significant low extent, e.g., value of bows around +/−1 μm.

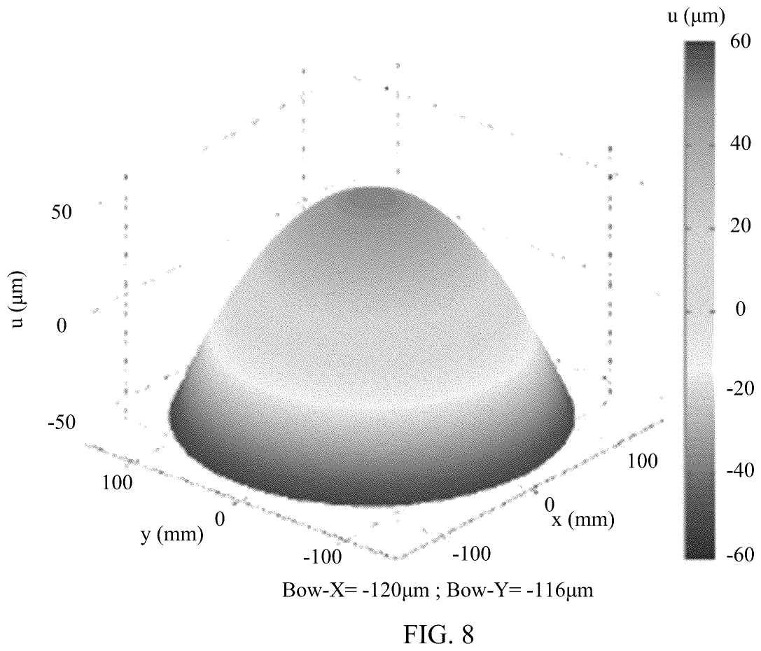

FIG. 8 shows a distribution of bow values of a semiconductor device before the formation of a dielectric layer (e.g., the dielectric layer 21) in accordance with some embodiments of the present disclosure. As shown in FIG. 8, the semiconductor device has a relatively large warpage. The value of bow along the x-axis (Bow-X) may be around −120 μm and the y-axis (Bow-Y) around −116 μm. Such warpage of the semiconductor device may degrade the intra-die overlay and/or inter-die overlay.

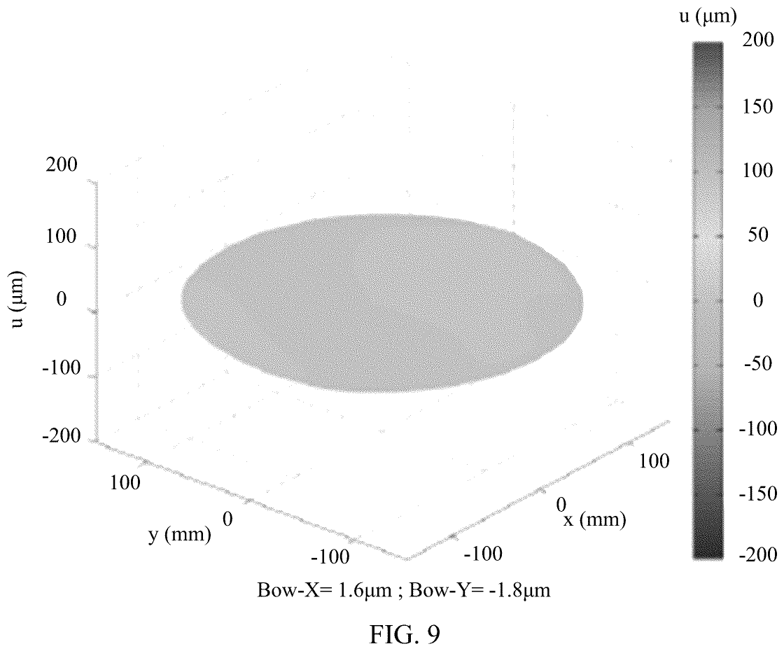

FIG. 9 shows a distribution of values of bow of a semiconductor device after the formation of a dielectric layer (e.g., the dielectric layer 21) of the method 300 in accordance with some embodiments of the present disclosure. As shown in FIG. 9, the semiconductor device has a relatively small warpage. The value of bow may be around +/−1 μm. The value of bow along the x-axis (Bow-X) may be around −1.6 μm and the y-axis (Bow-Y) around −1.8 μm.

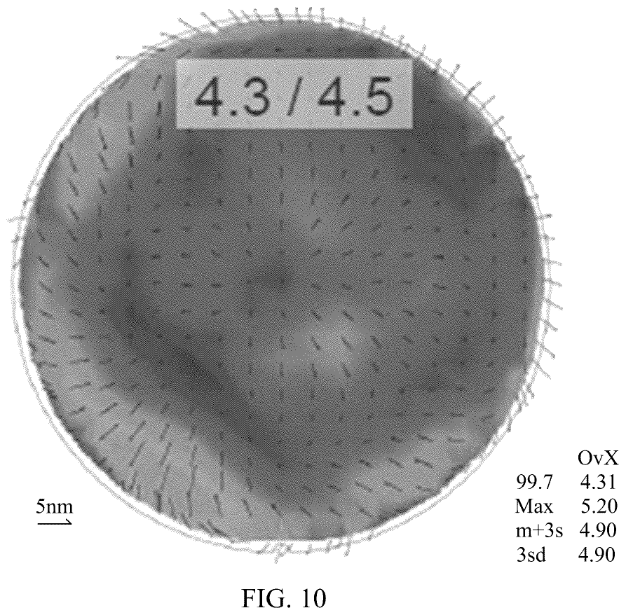

FIG. 10 shows a distribution of values of overlay (e.g., overlay errors) of a semiconductor device after the formation of a dielectric layer (e.g., the dielectric layer 21) of the method 300 in accordance with some embodiments of the present disclosure. The distribution of values of overlay shows a uniform profile, indicating that the overlay of the semiconductor device is significantly improved. In some embodiments, the average value of overlay within three standard deviation (3sd) may be around 4.31 nm. In some embodiments, the maximum value of overlay may be around 5.20 nm. In some embodiments, the value of overlay of the average value plus 3sd may be around 4.90 nm.

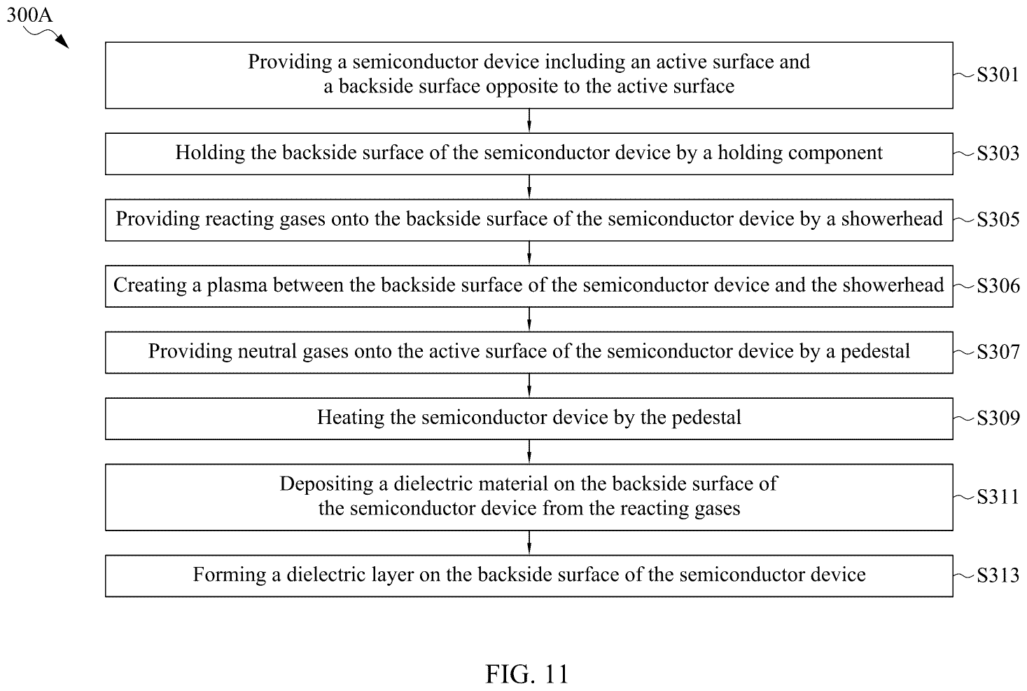

FIG. 11 is a flowchart of a method 300A of film deposition, in accordance with some embodiments of the present disclosure. Method 300A is similar to method 300 of FIG. 7 with differences therebetween as follows.

The method 300A further includes step 306: creating a plasma (e.g., the plasma 14) between the backside surface of the semiconductor device and the showerhead. The reacting gas as provided by the showerhead may interact with the plasma. The energy of the plasma may be transferred into the reacting gas, transforming the reacting gas into reactive radicals, ions and other highly excited species. The energetic species of the reacting gases then flow over the backside surface of the semiconductor device, where they are deposited as a dielectric material or a thin film. The energy of the plasma is transferred into the reacting gas, such that the temperature of the semiconductor device can be lower.

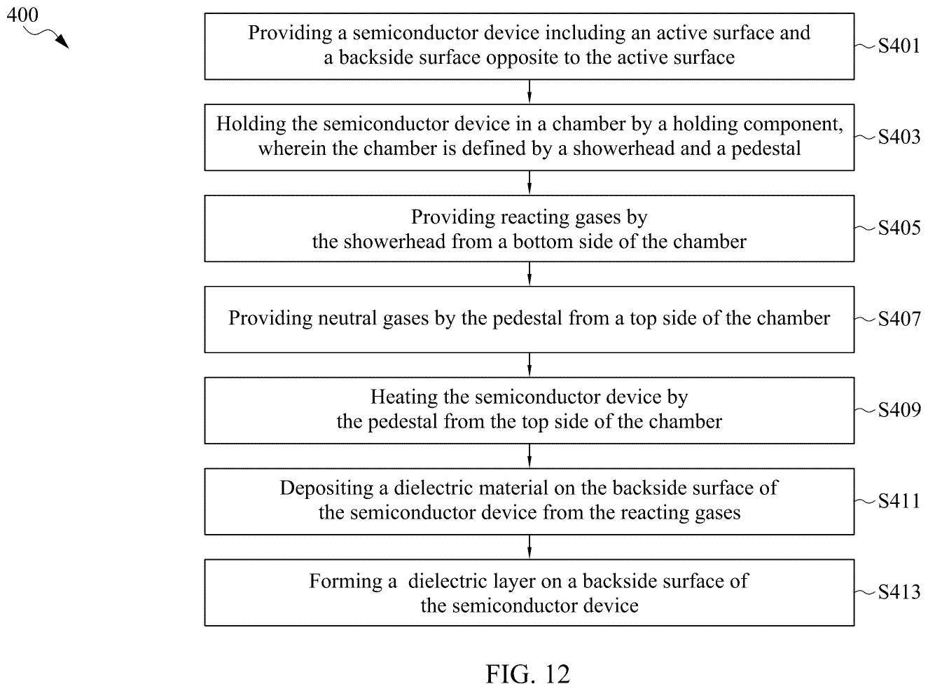

FIG. 12 is a flowchart of a method 400 of film deposition, in accordance with some embodiments of the present disclosure. The method 400 may be implemented by the tool 100 for film deposition.

The method 400 begins with operation S401 including providing a semiconductor device (e.g., the semiconductor device 20) including an active surface and a backside surface (e.g., active surface 201 and the backside surface 202 of the semiconductor device 20) opposite to the active surface. Prior to the operation S401, the method may further include loading the semiconductor device 20 via a port of the tool 100 for film deposition.

The method 400 continues with operation S403 including holding the semiconductor device in a chamber (e.g., the chamber C1) by a holding component (e.g., the holding component 13 of the film deposition tool). The chamber is defined by a showerhead (e.g., the showerhead 12 of the tool 100 for film deposition) and a pedestal (e.g., the pedestal 11 of the tool 100 for film deposition). Prior to the operation S403, the method 400 may further include actuating holding component 13 to receive the semiconductor device 20.

In some embodiments, holding the backside surface of the semiconductor device may further include holding the backside surface of the semiconductor device by a holding surface (e.g., the holding surface 133) of the holding component. The holding surface faces the pedestal. In some embodiments, holding the backside surface of the semiconductor device may further locate the semiconductor device, such that the backside surface of the semiconductor device faces the showerhead and the active surface of the semiconductor device faces the pedestal. In some embodiments, holding the backside surface of the semiconductor device may further expose a portion (e.g., the portion 2021 of the backside surface 202) of the backside surface by the holding component.

In some embodiments, holding the backside surface of the semiconductor device may further include locating the semiconductor device closer to the pedestal than the showerhead. A distance (e.g., the distance D3) between the active surface of the semiconductor device and the surface of the pedestal is less than a distance (e.g., the distance D4) between the backside surface of the semiconductor device and the surface of the showerhead.

The method 400 continues with operation S405 including providing reacting gases (e.g., the reacting gases G1) onto the backside surface of the semiconductor device by the showerhead from a bottom side (e.g., the surface 121 of the showerhead 12) of the chamber. The method 400 may further include distributing the reacting gases through a plurality of outlets of the showerhead.

The method 400 continues with operation S407 including providing neutral gases (e.g., the neutral gases G2) by the pedestal from a top side of the chamber. The method 400 may further include distributing the neutral gases through a plurality of outlets of the pedestal. The method may further include purging the reacting gases from the active surface of the semiconductor device by the neutral gases. As such, no dielectric material is deposited on the active surface of the semiconductor device.

The method 400 continues with operation S409 including heating the semiconductor device by the pedestal from the top side of the chamber. The temperature of the semiconductor device may be increased to reach a predetermined degree to facilitate the deposition of dielectric material. The temperature of semiconductor device may depend on the type of the dielectric material that is intended to deposit.

The method 400 continues with operation S411 including depositing a dielectric material on the backside surface of the semiconductor device from the reacting gases. In some embodiments, depositing the dielectric material may include pyrolytically decompositing the reacting gases on the substrate to provide a coating of a solid reaction product.

The method 400 continues with operation S413 including forming a dielectric layer (e.g., the dielectric layer 21) on the backside surface of the semiconductor device. In some embodiments, formation of the dielectric layer may include forming the dielectric layer on an exposed portion of the backside surface of the semiconductor device. The dielectric layer may not be formed on a covered portion of the backside surface of the semiconductor device. Owing to the existence of the neutral gas over the active surface of the semiconductor device, the dielectric layer may not be formed on the active surface of the semiconductor device. After step S313, the method may further include unloading the semiconductor device via a port of the film deposition tool.

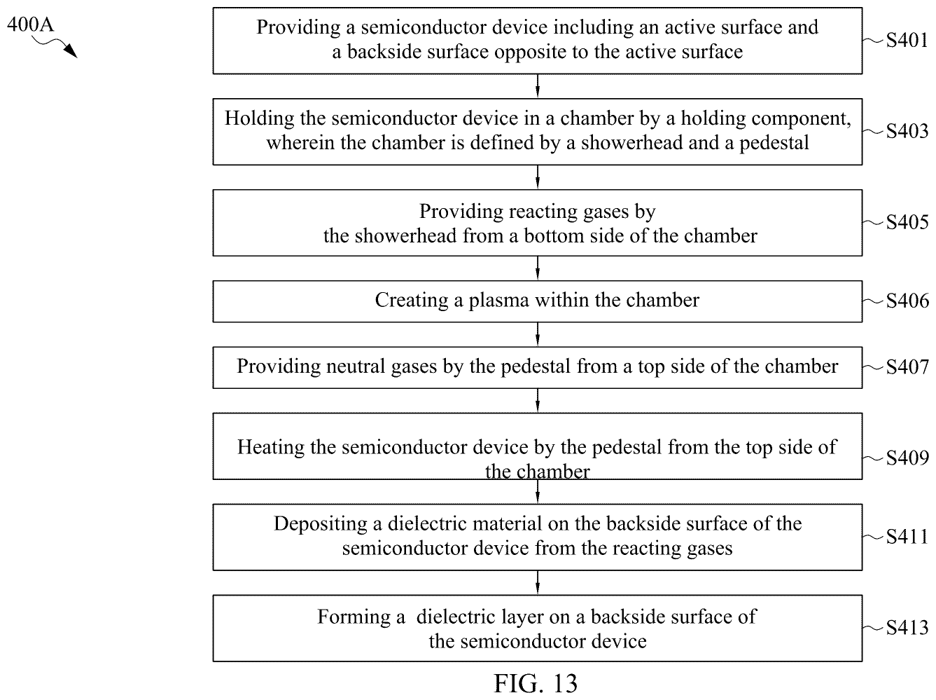

FIG. 13 is a flowchart of a method 400A of film deposition, in accordance with some embodiments of the present disclosure. The method 400A of film deposition of FIG. 13 is similar to the method 400 of film deposition of FIG. 12 with differences therebetween as follows.

The method 400A further includes step 406 of creating a plasma (e.g., the plasma 14) within the chamber. The reacting gas as provided by the showerhead may interact with the plasma. The energy of the plasma may be transferred into the reacting gas, transforming the reacting gas into reactive radicals, ions and other highly excited species. The energetic species of the reacting gases then flow over the backside surface of the semiconductor device, where they are deposited as a dielectric material or a thin film. The energy of the plasma is transferred into the reacting gas, such that the temperature of the semiconductor device can be lower.

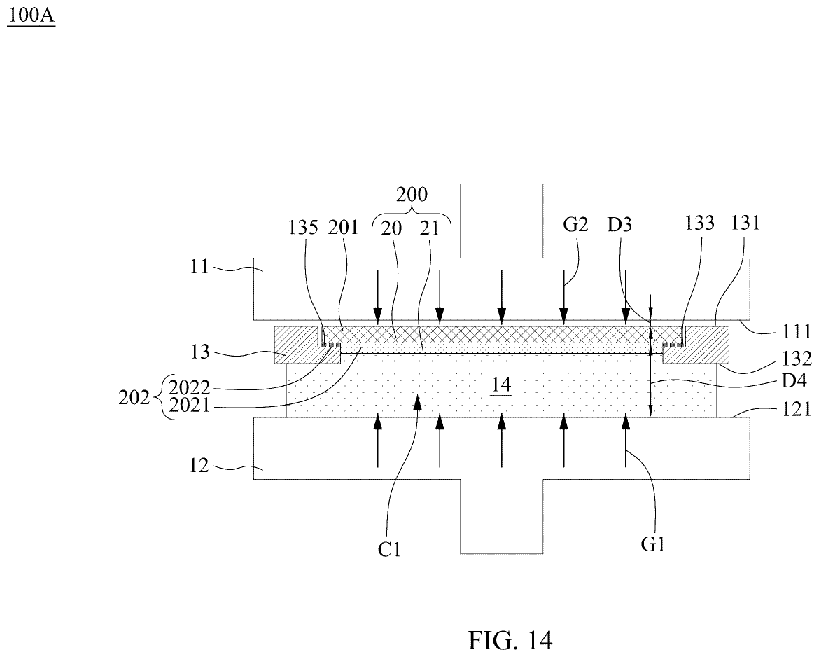

FIG. 14 is a schematic diagram of a tool 100A for film deposition in accordance with some embodiments of the present disclosure. Tool 100A of FIG. 14 is similar to tool 100 of FIG. 3 with differences therebetween as follows.

The holding component 13 of the tool 100A further includes a plurality of protruding portions 135 on the holding surface 133 of the holding component 13. The plurality of protruding portions 135 may be in contact with the portion 2022 of the backside surface 202 of the semiconductor device 20. The plurality of protruding portions 135 may reduce the contact area between the holding component 13 and the backside surface 202 of the semiconductor device 20. As such, the probability of crack of the semiconductor device 20 when being released from the holding component 13 may be lower.

One aspect of the present disclosure provides a method of film deposition including providing a semiconductor device including an active surface and a backside surface opposite to the active surface, holding the backside surface of the semiconductor device by a holding component, and forming a dielectric layer on the backside surface of the semiconductor device.

Another aspect of the present disclosure provides a method of film deposition including, holding a semiconductor device in a chamber by a holding component, wherein the chamber is defined by a showerhead and a pedestal, providing reacting gases by the showerhead from a bottom side of the chamber, and forming a first dielectric layer on a backside surface of the semiconductor device.

Another aspect of the present disclosure provides a semiconductor device including an active surface, a backside surface, and a dielectric layer. The backside surface is opposite to the backside surface. The dielectric layer is disposed on a first portion of the backside surface. The active surface of the semiconductor device is free from passivation layer remnants.

Another aspect of the present disclosure provides a film deposition tool, a pedestal, a showerhead, and a holding component. The showerhead is disposed below the pedestal. The holding component is disposed closer to the pedestal than the showerhead. The holding component has a holding surface facing the pedestal and configured to hold a backside surface of a semiconductor device.

The method of film deposition of the present disclosure includes providing a semiconductor device including an active surface and a backside surface opposite to the active surface; holding the backside surface of the semiconductor device by a holding component, and forming a dielectric layer on the backside surface of the semiconductor device to form the semiconductor device. The method of the present disclosure enables directly forming the dielectric layer on the backside surface of the semiconductor device in a single step to form the semiconductor device. The single step method as disclosed reduces costs and increases throughput. Since the active surface of the semiconductor device is physically separated from any parts of a tool for implementing the inventive method, no passivation layer (or protective layer) needs be deposited on the active surface of the semiconductor device. As such, the active surface of the semiconductor device may be free from any passivation layer remnants or any damage induced when removing the passivation layer. In the method of the present disclosure, the dielectric layer is directly formed on the backside surface of the semiconductor device in a single step without flipping or forming or removing passivation layer. The active surface of the semiconductor device is intact during the formation of the dielectric layer on the backside surface thereof. It prevents any remains of the passivation layer and/or any damage or characteristics shift induced during the removal of the passivation layer. Furthermore, in the method of the present disclosure, the dielectric layer is directly formed on the backside surface of the semiconductor device in a single step without forming or removing any temporary layer (e.g., the passivation layer). Based on the values of bow of the semiconductor device before the formation of the dielectric layer, the thickness or type of the dielectric layer may be determined to compensate the warpage of the semiconductor device to a significant low extent, e.g., value of bows around +/−1 μm.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A method of film deposition, comprising:
providing a semiconductor device including an active surface and a backside surface opposite to the active surface;
holding the backside surface of the semiconductor device by a holding component; and
forming a dielectric layer on the backside surface of the semiconductor device.

2. The method of claim 1, further comprising:
providing reacting gases by a showerhead;
creating a plasma between the backside surface of the semiconductor device and the showerhead, wherein the reacting gases interact with the plasma;
depositing a dielectric material on the backside surface of the semiconductor device from the reacting gases;
providing neutral gases onto the active surface of the semiconductor device by a pedestal; and.

3. The method of claim 2, further comprising heating the semiconductor device by the pedestal.

4. The method of claim 2, wherein the active surface of the semiconductor device is physically isolated from the pedestal.

5. The method of claim 1, wherein the active surface of the semiconductor device is physically isolated from the holding component.

6. The method of claim 2, wherein a distance between the active surface of the semiconductor device and the pedestal is less than a distance between the backside surface of the semiconductor device and the showerhead.

7. The method of claim 2, wherein holding the semiconductor device comprises holding the backside surface of the semiconductor device via a holding surface of the holding component, wherein the holding surface of the holding component faces the pedestal.

8. The method of claim 1, wherein the backside surface of the semiconductor device has a first portion covered by the holding component, the first portion is in contact with the holding component, and the holding component comprises a plurality of protruding portions in contact with the first portion of the backside surface of the semiconductor device.

9. The method of claim 1, wherein a value of bow of the semiconductor device decreases after the dielectric layer is formed.

10. The method of claim 1, wherein a plurality of semiconductor dies are disposed adjacent to the active surface, the semiconductor device comprises a wafer, and the holding component has an annular shape.

11. The method of claim 1, wherein the dielectric layer includes a thin film, and the dielectric layer is formed in a CVD process.

12. A method of film deposition, comprising:
holding a semiconductor device in a chamber by a holding component, wherein the chamber is defined by a showerhead and a pedestal;
providing reacting gases by the showerhead from a bottom side of the chamber; and
forming a first dielectric layer on a backside surface of the semiconductor device.

13. The method of claim 12, wherein the semiconductor device has an active surface opposite to the backside surface of the semiconductor device, the active surface of the semiconductor device faces a top side of the chamber, and the backside surface of the semiconductor device faces the bottom side of the chamber; and a distance between the active surface of the semiconductor device and the top side of the chamber is less than a distance between the backside surface of the semiconductor device and the bottom side of the chamber.

14. The method of claim 12, further comprising creating a plasma within the chamber; providing neutral gases by the pedestal from a top side of the chamber; and heating the wafer by the pedestal from a top side of the chamber; wherein the active surface is physically isolated from the pedestal, the backside surface of the semiconductor device has a first portion covered by the holding component.

15. A semiconductor device, comprising:
an active surface;
a backside surface opposite to the backside surface; and
a dielectric layer disposed on a first portion of the backside surface,
wherein the active surface of the semiconductor device is free from passivation layer remnants.

16. The semiconductor device of claim 15, wherein the active surface has substantially flat topography, the roughness of a central portion of the active surface and an edge portion of the active surface are substantially the same, and the dielectric layer is formed in a CVD process.

17. The semiconductor device of claim 15, wherein the semiconductor device has a value of bow around +/−1 μm, and a plurality of semiconductor dies are disposed on the active surface.

18. The semiconductor device of claim 15, wherein the backside surface of the semiconductor device includes a second portion exposed by the dielectric layer, and the second portion of the backside surface of the semiconductor device surrounds the first portion thereof.
